(19) United States
(12) Patent Application Publication
(10) Pub. No.: US 2008/0012087 A1
(43) Pub. Date: Jan. 17, 2008

(54) Bonded wafer avalanche photodiode and method for manufacturing same

(76) Inventors: Henri Dautet, Green Field Park (CA); Richard Seymour, Saint-Lazare (CA)

Correspondence Address: Iandiorio & Teska, 260 Bear Hill Road, Waltham, MA, 02451-1018, US

(21) Appl. No.: 11/725,661

(22) Filed: Mar. 20, 2007

Related U.S. Application Data
(60) Provisional application No. 60/793,084, filed on Apr. 19, 2006.

(51) Int. Cl. H01L 31/107; H01L 21/00

(52) U.S. Cl. 257/438; 438/91; 257/E31.063; 257/E21.001

(57) ABSTRACT

An avalanche photodiode includes a high quality electrooptically active substrate, a handle substrate bonded to the active substrate, and an avalanche photodiode active area formed in the high quality electrooptically active substrate including a high field region for generating avalanche current gain. By using a handle wafer bonded to the active substrate, the avalanche photodiode of the subject invention has a greater strength and thickness without the reduction of desirable electrical characteristics.

### RELATED APPLICATIONS

This application claims benefit of U.S. Provisional Application Ser. No. 60/793,084, filed on Apr. 19, 2006, entitled “Bonded Wafer Avalanche Photodiode and Method for Manufacturing Same”, incorporated herein by this reference.

### FIELD OF THE INVENTION

This invention relates to avalanche photodiodes and their methods of manufacturing.

### BACKGROUND OF THE INVENTION

An avalanche photodiode (APD) is a semiconductor device that converts light into an electrical signal. The APD detects low levels of electromagnetic radiation (photons) and is constructed so that a photon dislodges an electron (primary electron) and creates a hole-electron pair. These holes and electrons move in the opposite direction in the semiconductor device due to the electrical field that is applied across the photodiode. The movement of electrons through the structure is called photocurrent and it is proportional to the light intensity. In APDs, the primary electron hits other atoms with sufficient velocity and energy in the lattice structure to create additional electron-hole pairs. This cascade effect in avalanche photodiodes results in an effective gain and allows the detection of very low light levels. Indeed, even single photon detection is possible.

One application of an avalanche photodiode is disclosed in U.S. Pat. No. 6,525,305 B2, which is incorporated herein by reference. The '305 patent discloses a large current watchdog circuit that includes a variable impedance to protect the photodetector from high current levels.

APDs are typically manufactured on thin wafers. This is because the use of an APD wafer having an active thickness on the order of or greater than 200 μm results in undesirable electrical characteristics of the APD. However, the thinness of typical APD wafers may make them fragile during handling and high temperature furnacing. Additionally, the frail nature of these wafers may make them unsuitable for large dimension APDs due to breakage and poor yield.

One prior method for increasing the thickness of APD wafers is to grow a thin electrically active “epi” layer over a thicker substrate layer. A disadvantage to this approach, however, is that is difficult to grow crystals having an acceptable quality on top of the substrate. This difficulty of growing acceptable crystals increases as the thickness of the crystal increases. Another disadvantage is that the active layer can not be isolated from the substrate.

### BRIEF SUMMARY OF THE INVENTION

It is therefore an object of this invention to provide a new method for manufacturing an improved avalanche photodiode.

It is a further object of this invention to provide such an avalanche photodiode having a greater thickness.

It is a further object of this invention to provide such an avalanche photodiode having a greater strength.

It is a further object of this invention to provide such an avalanche photodiode having a greater electromagnetic detection in certain applications.

The subject invention results from the realization that an avalanche photodiode having greater thickness and strength can be manufactured by using a high quality optically active substrate, a handle substrate bonded to the active substrate, and an avalanche photodiode active area formed in the high quality optically active substrate that includes a high field region for generating avalanche current gain.

The subject invention, however, in other embodiments, need not achieve all these objectives and the claims hereof should not be limited to structures or methods capable of achieving these objectives.

This invention features an avalanche photodiode including a high quality electrooptically active substrate, a handle substrate bonded to the active substrate, and an avalanche photodiode active area formed in the high quality electrooptically active substrate including a high field region for generating avalanche current gain.

In one embodiment, the high quality electrooptically active substrate may include lightly doped silicon, which has a resistivity greater than 100 ohm×cm. The handle substrate may include heavily doped silicon, which has a resistivity less than 1 ohm×cm. The avalanche photodiode may further include a heavily doped layer between the lightly doped silicon layer and the heavily doped silicon layer. The avalanche photodiode may also further include an oxide layer between the lightly doped silicon layer and the heavily doped silicon layer. The high quality electrooptically active substrate may include p− silicon. The handle substrate may include p+ silicon. The avalanche photodiode may further include a p+ layer between the p− silicon layer and the p+ silicon layer. The avalanche photodiode may further include an oxide layer between the p− silicon layer and the p+ silicon layer. The high quality optically active substrate may include n− silicon. The handle substrate may include n+ silicon. The avalanche photodiode may further include an n+ layer between the n− silicon layer and the n+ silicon layer. The avalanche photodiode may further include an oxide layer between the n− silicon layer and the n+ silicon layer. The avalanche photodiode active area may include a gain region and a channel stop formed in the high quality optically active substrate. The avalanche photodiode may further include a passivated layer formed on the surface of the avalanche photodiode for protecting the surface of the avalanche photodiode. The avalanche photodiode may further include a junction formed adjacent the gain region for providing the high field region that generates avalanche current gain. The avalanche photodiode may further include an anti-reflection coating formed adjacent the diffused junction for reducing the reflection of radiation from the avalanche photodiode. The avalanche photodiode may further include a metallization layer for providing electrical contact. The avalanche photodiode may further include a well in the handle substrate. The avalanche photodiode may further include a heavily doped contact layer formed in the well. The heavily doped contact layer may include p+ silicon. The avalanche photodiode may further include a back metallization layer formed adjacent the heavily doped layer and adjacent the handle substrate.

This invention also features a method of manufacturing an avalanche photodiode, the method including providing a wafer having a high quality electrooptically active substrate and a handle substrate bonded to the active substrate, diffusing a gain region in the optically active substrate, and diffusing a junction adjacent the gain region to provide a high field region for generating avalanche current gain.

In one embodiment, the method may further include the step of diffusing a channel stop in the optically active substrate to reduce current leakage. The method may further include the step of passivating the surface of the avalanche photodiode for protecting the surface. The method may further include the step of providing an anti-reflective coating on the diffused junction for reducing the reflection of radiation. The method may further include the step of etching a well in the handle substrate. The method may further include providing a heavily doped layer in the well.

This invention further features an avalanche photodiode including a high quality active substrate, a handle substrate bonded to the active substrate, a well formed in the handle substrate, and an avalanche photodiode active area formed in the high quality active substrate, the active area including a gain region diffused in the active substrate, and a junction diffused adjacent the gain region to provide a high field region for generating avalanche current gain.

In one embodiment, the avalanche photodiode may further include a passivated layer formed adjacent the surface of the avalanche photodiode for protecting the surface of the avalanche photodiode. The handle substrate may be an active substrate.

### BRIEF DESCRIPTION OF THE DRAWINGS

Other objects, features and advantages will occur to those skilled in the art from the following description of a preferred embodiment and the accompanying drawings, in which the attached figures are embodiments of the bonded wafer APD and its method of manufacture.

FIG. 1 is a schematic cross-sectional view of one example of a bonded wafer avalanche photodiode in accordance with the subject invention;

FIGS. 2-5 are schematic diagrams illustrating the primary steps associated with the manufacture of the bonded wafer avalanche photodiode of FIG. 1;

FIGS. 6-9 are schematic diagrams that illustrate the primary steps associated with the manufacture of an alternative embodiment of a bonded wafer avalanche photodiode in which a well is etched in the back of the avalanche photodiode;

FIG. 10 is a schematic cross-sectional view of a front entry avalanche photodiode; and

FIG. 11 is a schematic cross-sectional view of a rear entry avalanche photodiode.

Although specific features of this invention are shown in some drawings and not others, this is for convenience only as each feature may be combined with any or all of the other features in accordance with the invention.

### DISCLOSURE OF THE PREFERRED EMBODIMENT

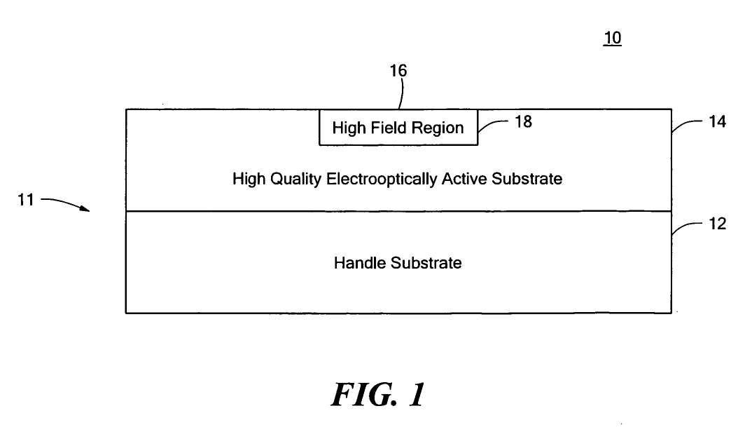

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

Whereas APDs in the prior art are typically manufactured on thin wafers, avalanche photodiode (APD) 10, FIG. 1, in accordance with this invention includes wafer 11 comprising handle substrate 12 bonded to high quality optically active substrate 14. Optically active substrate 14 includes active area 16 that includes high field region 18 for generating avalanche current gain. Handle substrate 12 may be purchased with active substrate 14 already bonded thereto. Alternatively, handle substrate 12 may be purchased separately from active substrate 14 and handle substrate 12 can be subsequently bonded to active substrate 14.

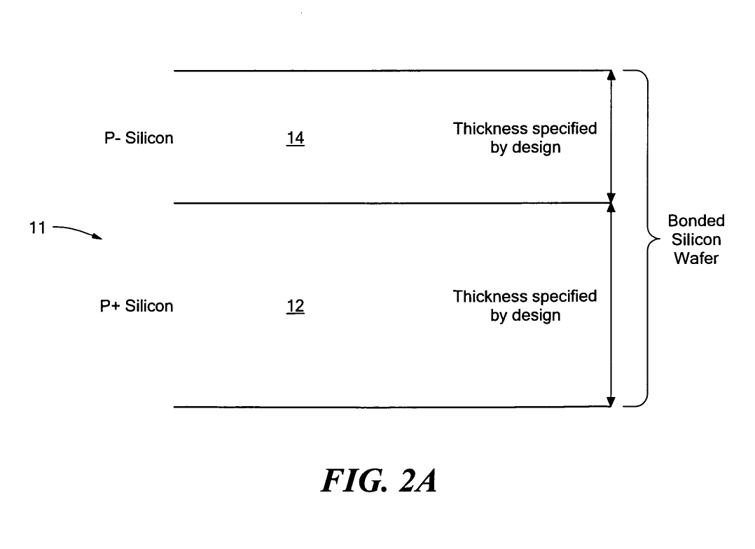

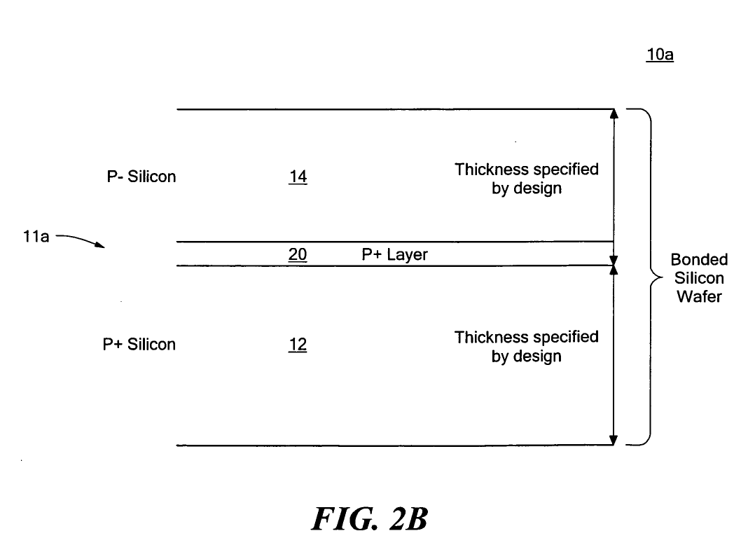

One method of manufacturing bonded wafer APD 10 begins with providing a wafer 11, FIG. 2A, in which handle substrate 12 is bonded to optically active substrate 14. Handle substrate 12 may have a thickness of 20-1000 μm, but preferably has a thickness of 250-500 μm. Active substrate 14 may have the thickness of 2-200 μM, but preferably has a thickness of 6-150 μm.

Handle substrate 12 typically includes heavily doped silicon which is p+ silicon, but may alternatively be n+ silicon depending on the type of APD. Optically active substrate 14 includes lightly doped silicon which is p− silicon, but may likewise alternatively be n− silicon depending on the type of APD.

An alternative embodiment of bonded wafer 11a, FIG. 2B, includes a heavily doped silicon layer 20, FIG. 2A, which is added to active substrate 14 prior to bonding active substrate 14 to handle substrate 12. Heavily doped silicon layer 20 improves the interface quality between substrates 12 and 14. Heavily doped silicon layer 20 may include either a p+ layer or an n+ layer depending on the type of APD. Alternatively, rather than using a heavily doped silicon layer, an oxide layer may be used between substrates 12 and 14 to improve interface quality.

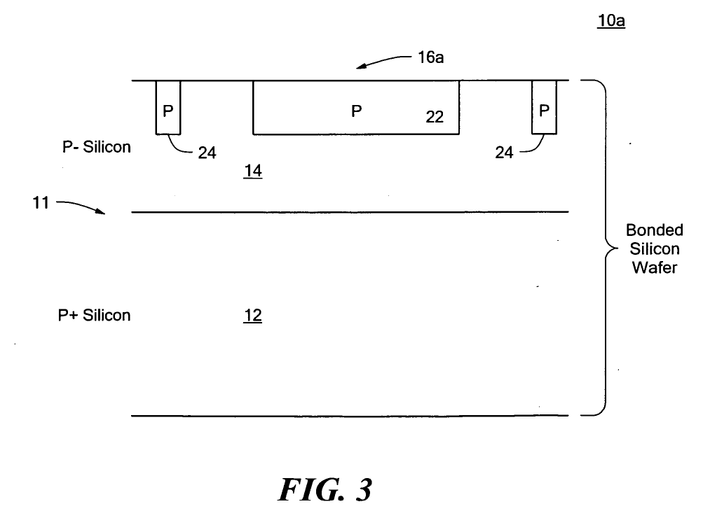

Gain region 22, FIG. 3 and channel stops 24 are diffused in the APD active area 16a of optically active substrate 14. Channel stops 24 provide a barrier to prevent small leakage paths from traveling to the outside of optically active substrate 14.

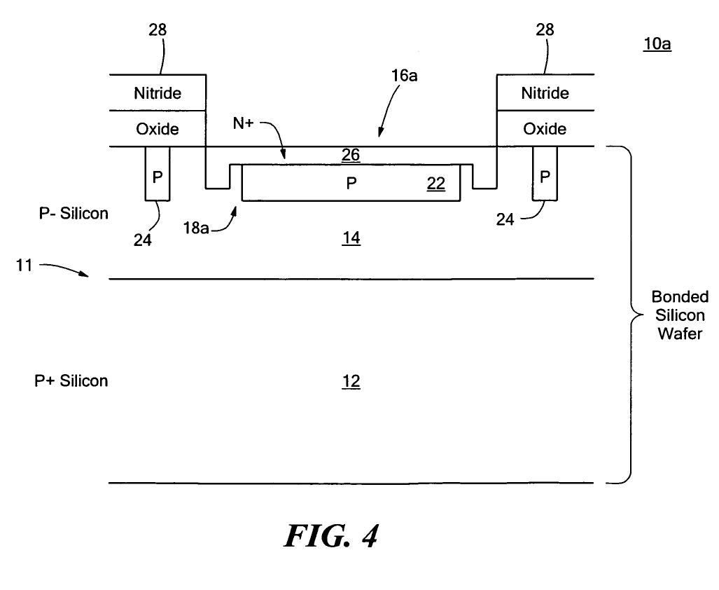

Junction 26, FIG. 4 is diffused adjacent gain region 22 to provide high field region 18a which generates the avalanche current gain of APD 10a. A passivated layer 28 is formed on the surface of APD 10a for protecting the surface of the APD. Passivated layer 28 preferably includes silicon nitride and silicon oxide.

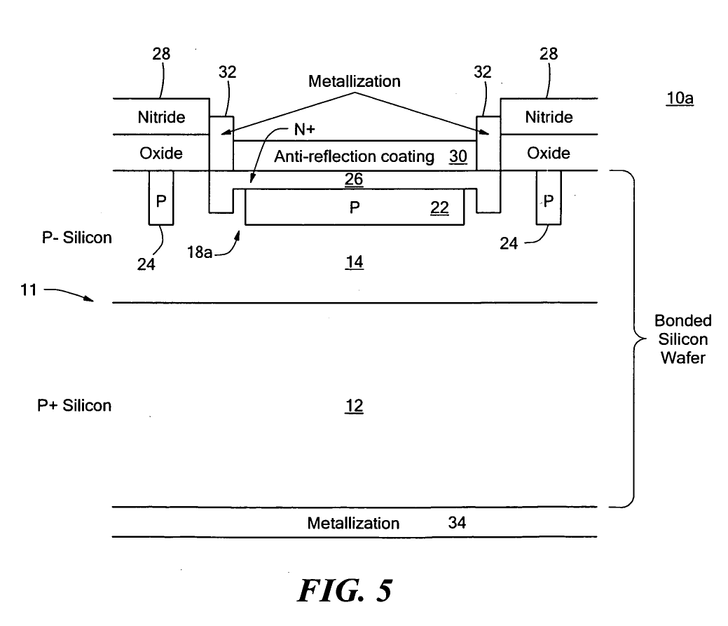

Anti-reflection coating 30, FIG. 5 is formed adjacent diffused junction 26 for reducing the reflection of radiation from APD 10a. Metallization layers 32 and 34 are provided for electrical contact. Metallization layer 32 is formed adjacent diffused junction 26 and anti-reflection coating 30. Metallization layer 34 is formed adjacent handle substrate 12.

Thus, with APD 10a of FIG. 5, high quality optically active substrate 14 is provided with a strong handle substrate 12 to provide an APD having greater thickness and strength than those of the prior art, without reducing the desirable electrical characteristics of the APD.

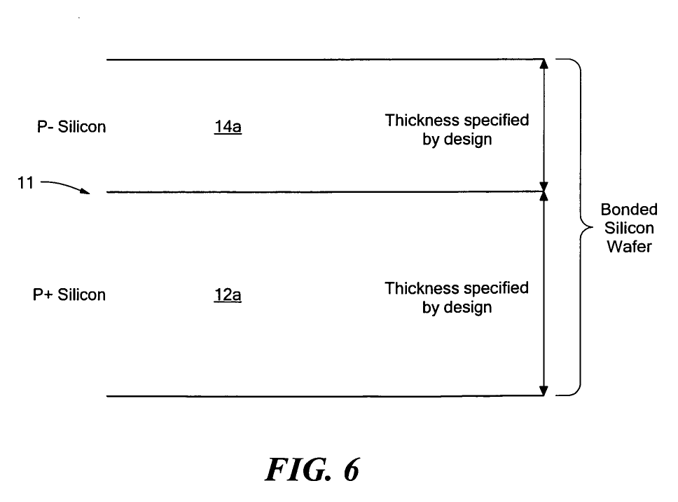

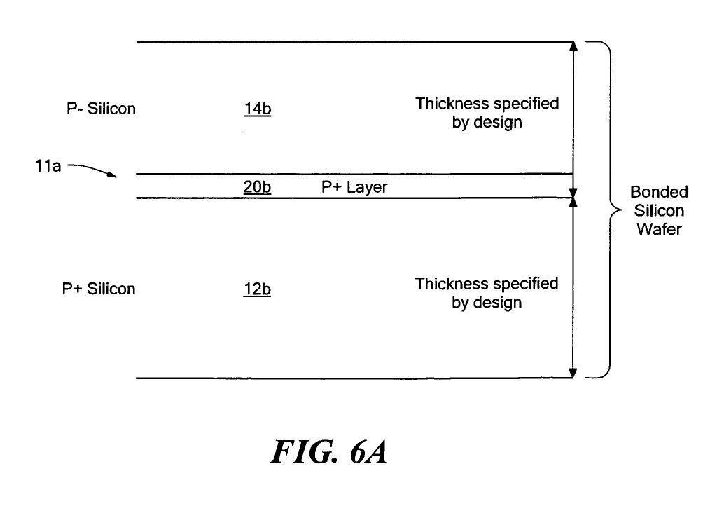

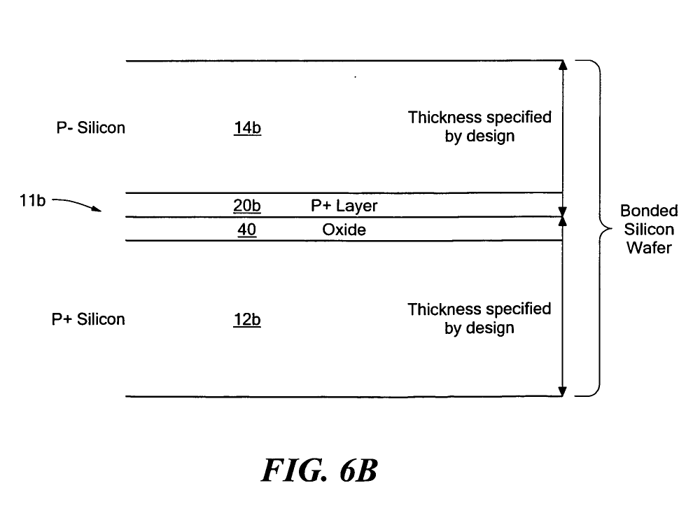

In one alternative embodiment, bonded silicon wafer 11, FIG. 6, is provided which includes handle substrate 12b and active substrate 14b. Wafer 11a may additionally include a heavily doped layer 20b, FIG. 6A, which is added prior to bonding substrates 12b and 14b as done in FIG. 2A. As with heavily doped layer 20, heavily doped layer 20a may include either a p+ layer or an n+ layer, depending on the type of APD. Wafer 11c may include oxide layer 40, FIG. 6B, which may be added in addition to heavily doped layer 20b.

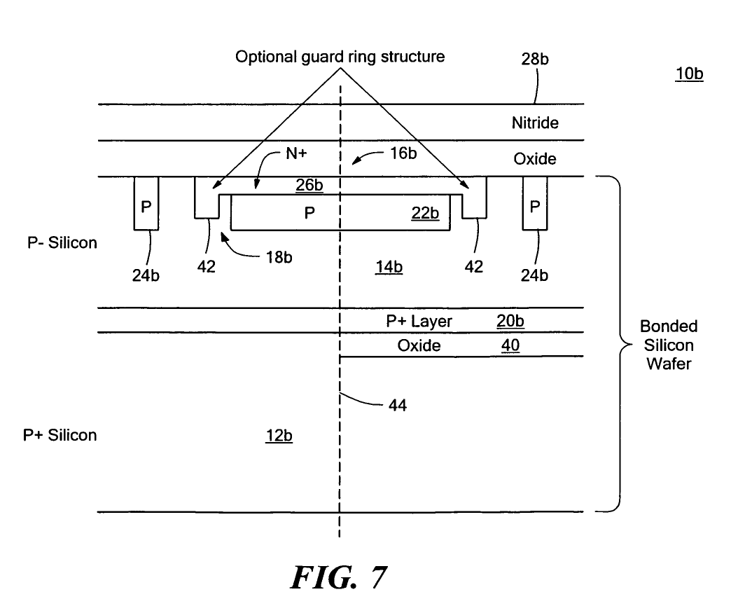

To provide APD 10b, FIG. 7 gain region 22a and junction 26a are diffused in active area 16a of high quality active substrate 14 to create high gain region 18b. Optionally, guard ring structure 42 may be provided to reduce the electric field at the edge of the junction. Dividing line 40 is provided to show that APD 10b may include oxide layer 40 but may be manufactured without the oxide layer.

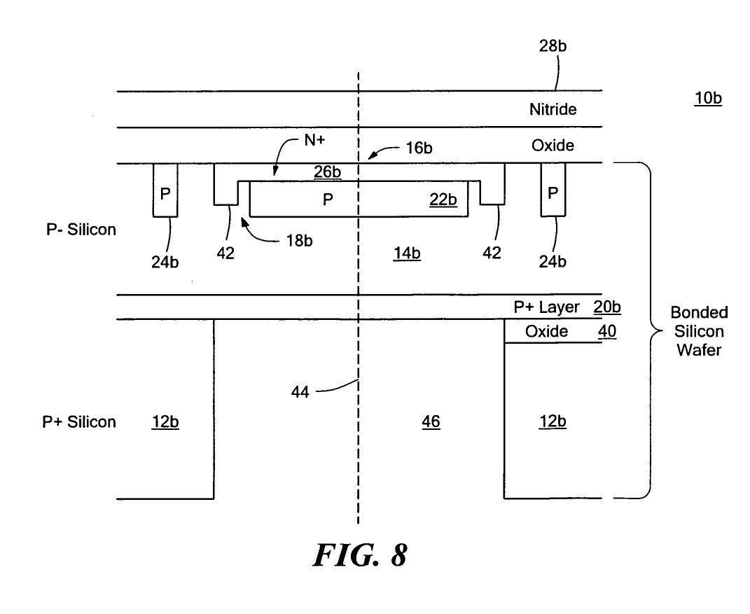

Well 46, FIG. 8, is etched in the back surface of handle substrate 12b. The etching of well 46 also removes oxide layer 40 if one is present in APD 10b.

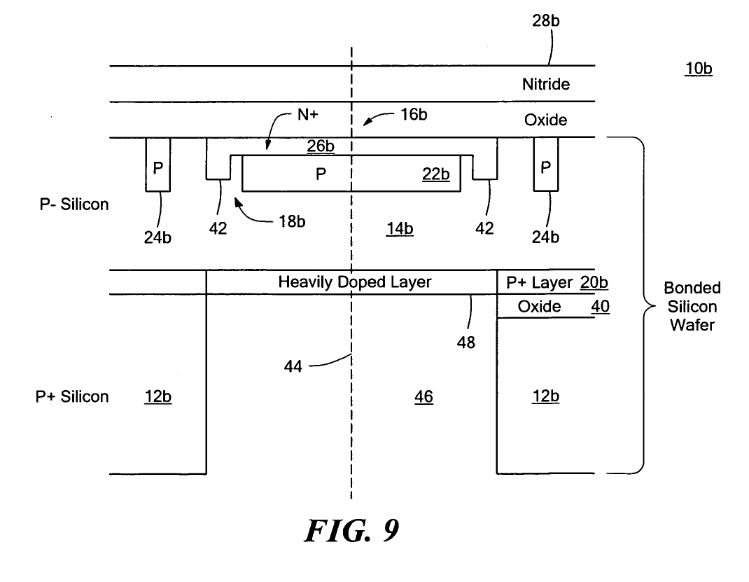

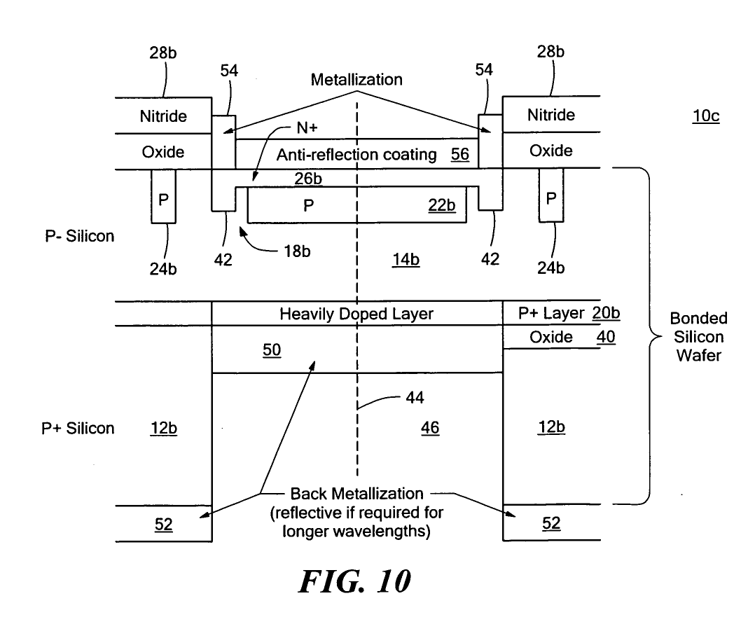

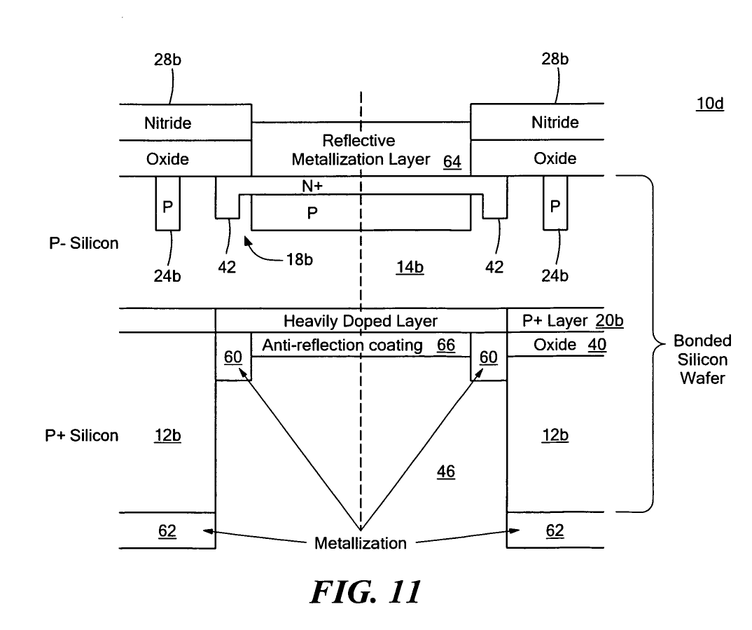

Heavily doped layer 48, FIG. 9, is provided through the back contact of well 46 to provide improved performance of APD 10b. A front entry APD 10b is formed by adding back metallization layers 50 and 52 and front metallization layer 54 and anti-reflection coating 56. Alternatively, a rear entry standard APD 10d, FIG. 10, is provided by adding metallization layers 60 and 62 and anti-reflection coating 66 adjacent well 46 and adding reflective metallization layer 64 adjacent high gain region 18b to the APD of 10b of FIG. 9.

The words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

What is claimed is:

1. An avalanche photodiode comprising:
a high quality electrooptically active substrate;
a handle substrate bonded to the active substrate; and
an avalanche photodiode active area formed in the high quality optically active substrate including a high field region for generating avalanche current gain.

2. The avalanche photodiode of claim 1 in which the high quality electrooptically active substrate includes lightly doped silicon.

3. The avalanche photodiode of claim 2 in which the handle substrate includes heavily doped silicon.

4. The avalanche photodiode of claim 3 further including a heavily doped layer between the lightly doped silicon layer and the heavily doped silicon layer.

5. The avalanche photodiode of claim 3 further including an oxide layer between the lightly doped silicon layer and the heavily doped silicon layer.

6. The avalanche photodiode of claim 2 in which the high quality electrooptically active substrate includes p− silicon.

7. The avalanche photodiode of claim 6 in which the handle substrate includes p+ silicon.

8. The avalanche photodiode of claim 7 further including a p+ layer between the p− silicon layer and the p+ silicon layer.

9. The avalanche photodiode of claim 7 further including an oxide layer between the p− silicon layer and the p+ silicon layer.

10. The avalanche photodiode of claim 2 in which the high quality electrooptically active substrate includes n− silicon.

11. The avalanche photodiode of claim 10 in which the handle substrate includes n+ silicon.

12. The avalanche photodiode of claim 11 further including an n+ layer between the n− silicon layer and the n+ silicon layer.

13. The avalanche photodiode of claim 11 further including an oxide layer between the n− silicon layer and the n+ silicon layer.

14. The avalanche photodiode of claim 1 in which the avalanche photodiode active area includes a gain region and a channel stop formed in the high quality optically active substrate.

15. The avalanche photodiode of claim 14 further including a passivated layer formed on the surface of the avalanche photodiode for protecting the surface of the avalanche photodiode.

16. The avalanche photodiode of claim 14 further including a junction formed adjacent the gain region for providing the high field region that generates avalanche current gain.

17. The avalanche photodiode of claim 16 further including an anti-reflection coating formed adjacent the diffused junction for reducing the reflection of radiation from the avalanche photodiode.

18. The avalanche photodiode of claim 1 further including a well in said handle substrate.

19. The avalanche photodiode of claim 18 further including a heavily doped contact layer formed in the well.

20. The avalanche photodiode of claim 19 in which the heavily doped contact layer includes p+ silicon.

21. The avalanche photodiode of claim 19 further including a back metallization layer formed adjacent the heavily doped layer and adjacent the handle substrate.

22. A method of manufacturing an avalanche photodiode, the method comprising:
providing a wafer having a high quality electrooptically active substrate and a handle substrate bonded to the active substrate;
diffusing a gain region in the electrooptically active substrate; and
diffusing a junction adjacent the gain region to provide a high field region for generating avalanche current gain.

23. The method of claim 22 further including the step of diffusing a channel stop in the electrooptically active substrate to reduce current leakage.

24. The method of claim 22 further including the step of passivating the surface of the avalanche photodiode for protecting the surface.

25. The method of claim 24 further including the step of providing an anti-reflective coating on the diffused junction for reducing the reflection of radiation.

26. The method of claim 22 further including the step of etching a well in the handle substrate.

27. The method of claim 26 further including providing a heavily doped layer in the well.

28. An avalanche photodiode comprising:
a high quality active substrate;
a handle substrate bonded to the active substrate;
a well formed in the handle substrate; and
an avalanche photodiode active area formed in the high quality active substrate, the active area including:
a gain region diffused in the active substrate, and
a junction diffused adjacent the gain region to provide a high field region for generating avalanche current gain.

29. The avalanche photodiode of claim 28, further including a passivated layer formed adjacent the surface of the avalanche photodiode for protecting the surface of the avalanche photodiode.

30. The avalanche photodiode of claim 28 in which the handle substrate is an active substrate.
